(19) United States
(12) Patent Application Publication
(10) Pub. No.: US 2005/0061362 A1
(43) Pub. Date: Mar. 24, 2005

(54) Geothermal power generator

(76) Inventor: Charles Burgoyne Graham, Sudbury (CA)

Correspondence Address: Borealis Technical Limited, 23545 NW Skyline Blvd, North Plains, OR, 97133-9204, US

(21) Appl. No.: 10/944,639

(22) Filed: Sep. 17, 2004

(30) Foreign Application Priority Data
Sep. 18, 2003 (GB) GB0321864.1

(51) Int. Cl. H01L 31/00

(52) U.S. Cl. 136/252

(57) ABSTRACT

A Geothermal Power Generator which includes apparatus and method for the in-situ recovery of geothermal energy using thermotunnelling or thermionic converters. These are diode devices that produce electricity when a temperature gradient is applied across them. The electricity thus produced in a downhole environment is conducted to the surface where it can be used as an effective electrical source.

### CROSS-REFERENCE TO RELATED APPLICATIONS

This application claims the benefit of United Kingdom Application No. 0321864.1, filed Sep. 18, 2003.

### BACKGROUND OF THE INVENTION

The invention relates to direct thermal-to-electric energy conversion systems for in situ recovery of underground geothermal energy.

High temperature geological areas, commonly referred to as geothermal areas, exist throughout the world. These areas are a natural source of heat that can be used to generate electricity. This can be done by drilling a hole or by making use of existing holes, such as abandoned oil wells. There are a number of current systems that utilize these areas to produce electricity, but there are several problems associated with them.

One system used is hydroelectric power—geothermal heat is used to heat up water to high temperatures, which produces steam to power turbines. This involves either using natural hot springs or pumping water down holes, bringing the water to the surface and setting up a generating system above ground. There are a lot of inefficiencies involved in this system, as heat is lost along the way. It is costly to build and maintain, as there are many moving parts, all of which are subject to wear and tear. Furthermore, the circulating water (or other fluid) often dissolves large quantities of minerals and becomes very corrosive. The dissolved minerals also often precipitate out as the fluid escapes or is pumped from underground. The precipitating minerals can effectively plug the well.

Another system uses dry steam—steam from geothermal areas is used directly to power turbines. This avoids the problems that arise when water is used, but still necessitates the building of a generating system and the cost and time that this involves.

Other systems have been invented to utilize the heat energy to produce electricity in a downhole environment, thus avoiding the need to bring heat to the surface, through liquid or any other medium, and avoiding the problems encountered with water as mentioned above. These systems use devices that can produce electricity by the simple application of heat to the device. The electricity produced in this way needs only to be conducted to the surface, where it can be used instantly. One prior art method of doing this involves thermoelectric devices. U.S. Pat. No. 6,150,601, for example, refers to the use of thermoelectric devices to generate electricity in a downhole environment, both for the benefit of recharging battery packs and to generate an independent electricity supply.

This avoids many of the problems of previous systems, but has considerable drawbacks. Thermoelectric devices generate power by using special materials and configurations that force heat to push electrons from one side of the device to the other.

The biggest problem with thermoelectrics is that while heat pushes electrons in one direction, the material itself redistributes most of that heat through simple conduction. This means that most of the heat is not usefully harnessed, and instead flows through the system in all directions, reducing efficiency.

Similar ideas have been developed using thermionic systems as opposed to thermo-electric systems. These have the advantage of being far more efficient because there is a physical gap between two substrates, which prevents heat from returning to its source. However, prior art inventions involving thermionic systems are only able to function efficiently at very high temperatures, thus limiting the areas in which they can be used. Furthermore, prior art systems include expensive custom designed units fully encircling centralized heat pipes, such as U.S. Pat. No. 4,047,093 to Levoy. Patent Application number WO99/13562 describes a method for generating electricity from any heat source using thermotunneling converters.

These are diode devices made by placing two materials very close to each other so that energetic electrons can tunnel from one material to the other. By, tapping this electron flow, usable electric current can be extracted. The gap acts as a heat barrier and prevents the heat from being transferred by mere conduction.

This system has been shown to be extremely efficient and has the added advantage of being able to harness lower grade heat than both turbine systems and the annular prior art thermionic systems mentioned above.

### BRIEF SUMMARY OF THE INVENTION

From the foregoing, it may be appreciated that a need has arisen for a geothermal power generation system that allows for the efficient production of power in the downhole environment.

In one aspect, the present invention is an apparatus for generating electricity in a downhole environment. The apparatus comprises a fluid filled vessel located in the downhole environment, in which the fluid is in thermal contact with heat dissipated by hot strata. The vessel has a double-walled pipe within it with sufficient space for the fluid to flow around the exterior of the pipe. A number of thermotunneling or thermionic converters are located between the two walls of the double-walled pipe. A fluid is also disposed within the interior of the pipe, and is cooler than the fluid around the exterior of said pipe. One surface of the thermotunneling or thermionic converters is in thermal contact with the fluid round the exzterior of the pipe, and the other surface of the converter is in thermal contact with said cooler fluid. The apparatus also comprises suitable wiring for connecting the converters together.

In another aspect, the present invention is a method for generating electricity in a downhole environment. The method comprises thermally contacting one surface of a number of thermotunneling or thermionic converters with a geothermal heat source, and thermally contacting the other surface of the converters to a heat sink.

In a further embodiment, electricity produced by the converters is conducted out of the downhole environment by suitable wiring means.

In a yet further embodiment, electricity produced by the converters is conducted to other devices in the downhole environment that require electrical power.

The present invention utilizes the efficiency of thermotunneling converters by providing an apparatus within which they can produce electricity in a downhole environment, using the heat energy found in geothermal areas.

This invention solves many of the problems found in prior art. Thermotunnelling converters have the advantage of being far more efficient than present thermal-to-electric energy conversion systems, such as thermoelectric devices, and can also be used at a wide variety of temperatures. They may also be constructed inexpensively and reliably, and are resistant to vibration and shock.

A further advantage of the present system is that it utilizes the heat found in geothermal sources without needing the introduction of a fluid, thus providing greater efficiency and economical savings and reducing the likelihood that the system may eventually become blocked because of the buildup of minerals. It also involves no moving parts and will therefore have higher reliability and prolonged lifetime.

### BRIEF DESCRIPTION OF THE SEVERAL VIEWS OF THE DRAWING

For a more complete explanation of the present invention and the technical advantages thereof, reference is now made to the following description and the accompanying drawing in which:

FIG. 1 is a vertical cross section of a first embodiment of the Geothermal Power Generator.

FIG. 2 is a horizontal cross section of a first embodiment of the Geothermal Power Generator.

FIG. 3 is a cutaway view of a first embodiment of the Geothermal Power Generator.

FIG. 4 is a vertical cross section of a second embodiment of the Geothermal Power Generator, showing separate sections for hot and cold fluid.

FIG. 5 is a vertical cross-section of a further embodiment of the Geothermal Power Generator, showing an inlet for pumping cold water from a ground source into the interior of the pipe to act as a heat sink.

FIG. 6 is a vertical cross-section of a further embodiment of the invention, showing the generator resting on the base of a geothermal well.

### DETAILED DESCRIPTION OF THE INVENTION

In the following disclosure, the term “thermotunneling converter” is used to describe the power-generating element in the present invention. It is to be understood that this term is descriptive of a gap diode in which the separation of two electrodes is of the order of 1 to 100 nm. In such a device, electrons may tunnel from electrode one to the other, as described in the foregoing. They may also be emitted in a thermionic fashion, and travel ballistically from one electrode to the other. Thus the term “thermotunneling converter” also encompasses a thermionic converter in which the electrodes are separated by a small gap.

The Geothermal Power Generator provides a novel way for the in situ recovery of underground geothermal energy.

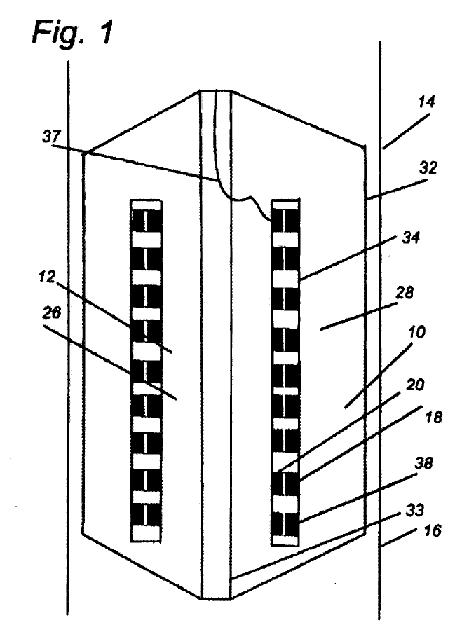

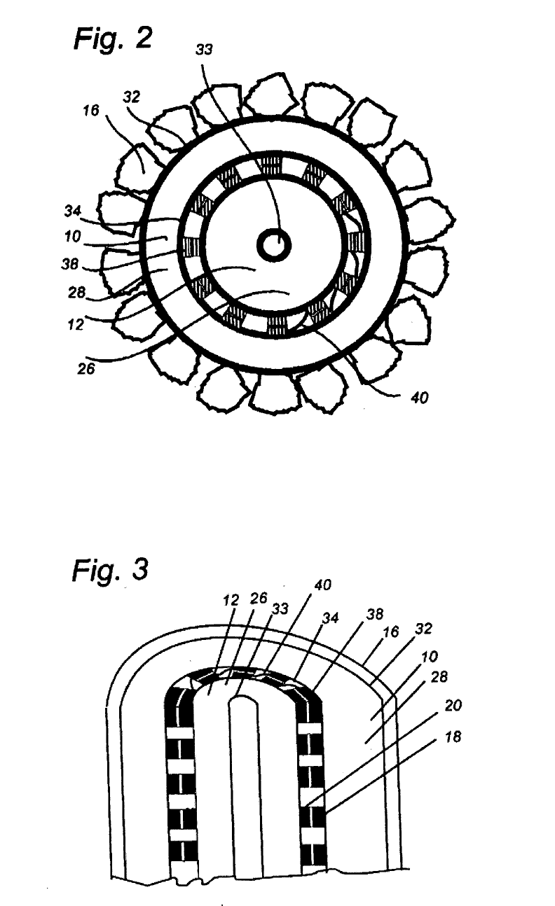

FIGS. 1-3 show different features of a primary embodiment of the Geothermal Power Generator. The primary embodiment of the invention consists of a sealed fluid-filled vessel 32, of sufficient length that when it is located in a downhole environment, the lower part will be significantly hotter than the upper part. The diameter of the sealed fluid-filled vessel 32 is less than the diameter of the hole, such that the vessel 32 may be fitted down the hole close enough to the wall of the hole to absorb the heat contained in the surrounding rock wall 16. Vessel 32 comprises a thermally conductive exterior, and can be made from any suitably conductive material, such as copper, aluminum, stainless steel or stainless steel alloys. Useful stainless steel alloys include those with nickel, molybdenum or tungsten. However, the invention is not limited to these specific materials.

Disposed within fluid-filled vessel 32 is a double-walled pipe 34, also made of a thermally conductive material, such as those mentioned above.

In a preferred embodiment, pipe 34 is of shorter length than fluid-filled vessel 32, and positioned to allow easy fluid flow around all exterior surfaces of pipe 34. Between the double walls of said double-walled pipe are a plurality of thermotunneling converters 38, each comprising a first surface 18 and a second surface 20. Each first surface 18 is in thermal contact with the thermally conductive fluid 10 which flows around the exterior 28 of pipe 34 inside fluid filled vessel 32.

The interior 26 of pipe 34 comprises a fluid 12 which is cooler than the fluid 10 around the exterior 28 of said pipe. In one embodiment, the fluid 12 comprises the same fluid as the fluid 10 which flows around the exterior 28 of pipe 34, but due to the fluid having been circulated near the cooler rock 14 at the top of the vessel, the fluid 12 in the interior 26 of pipe 34 is cooler than the fluid 10 around the exterior 28 of pipe 34. This represents a closed loop system.

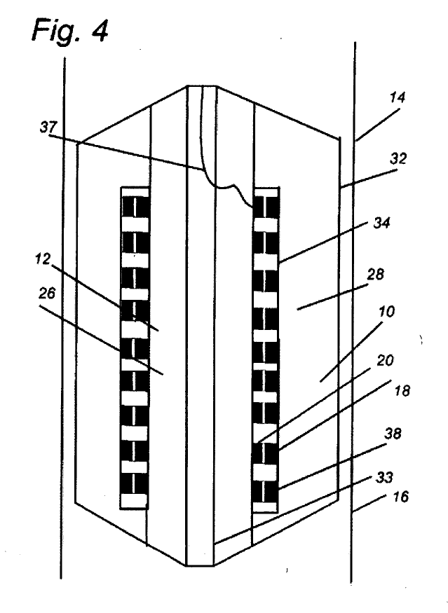

Referring now to FIG. 4, in a second embodiment, the fluid 12 in the interior 26 of the pipe 34 is disconnected from the fluid 10 around the exterior 28 of the pipe 34. In a third embodiment, the fluid in the interior of pipe 34 may be actively cooled or may have heat actively extracted from it.

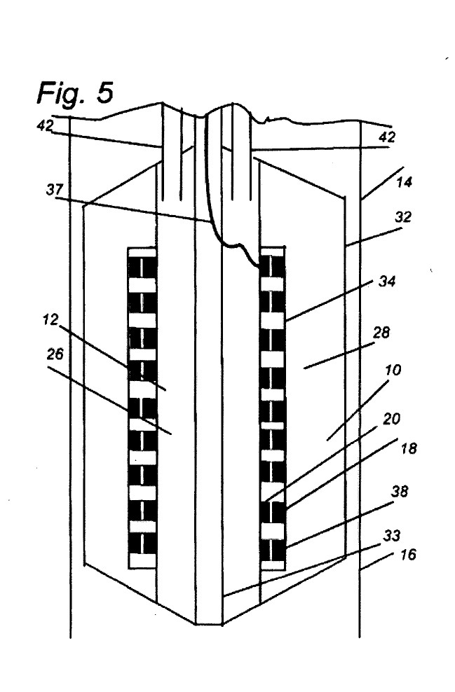

Referring now to FIG. 5, in a fourth embodiment a source of water at ground temperature is pumped into the interior of pipe 34 by means of a cooling mechanism 42. This represents an open loop system.

Each second surface 20 of the thermotunneling converters 38 is in thermal contact with the fluid 12 disposed within the interior 26 of pipe 34. Any type of fluid may be used that is substantially thermally conductive, such as liquid graphite, pure water, brine or machine oil. Furthermore, the fluid is not limited to liquids but may include thermally conductive gases. A fluid with an appropriate specific heat capacity will be chosen, taking into account the dimensions of the vessel, the heat to be transferred and whether an open or closed loop system is in operation.

In a preferred embodiment a supporting structure 33 runs through the center of vessel 32. The supporting structure 33 comprises a vertical shaft axially aligned with vessel 32 and is made of a material of sufficient strength to support the weight of fluid filled vessel 32 in a downhole environment for an extended period. Supporting structure 33 may also provide a cableway through which electricity produced by thermotunnelling converters 38 may be conducted to the surface.

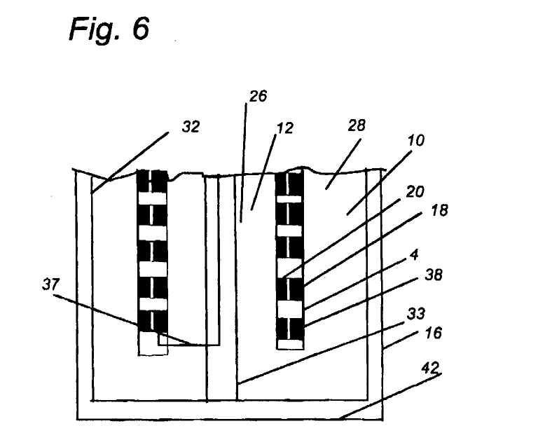

Referring now to FIG. 6, alternatively, vessel 32 stands on the base 42 of the hole during usage. One embodiment may include sliding support for raising and lowering the vessel from the hole. Prior art methods for extending the generator from the surface into a downhole environment are well known, as are pulley systems to allow for the generator to be repaired or relocated. In another embodiment vessel 32 is cemented into the well. This may be done in a telescopic manner.

Vessel 32 is situated inside a geothermal well, in thermal contact with the rock surface 16, where the heat dissipated by rock surface 16 is sufficient that the lower part of vessel 32 becomes hot enough to heat the fluid 10 inside vessel 32 and causes it to rise and descend through the double-walled pipe 34 by convection. The interior 26 of the double-walled pipe 34 has no contact with hot rock surface 16. Rock temperatures are progressively cooler nearer to the ground surface, and this will have the effect of cooling the fluid 10 slightly as it rises up vessel 32 due to convection currents and comes into contact with cool rock 14. Furthermore, as the thermotunneling converters 38 use the heat energy contained in the fluid 10 they effectively cool it down. When the fluid 12 then descends down the interior 26 of the pipe 34 it will be significantly cooler than the fluid 10 in the outer part 28 of the vessel 32. This will effectively set up a temperature differential across double-walled pipe 34, and the thermotunneling converters 38 inside it will produce electricity.

Another embodiment of the invention comprises a shorter fluid filled vessel 32 which is not long enough to utilize the temperature gradient found in a geothermal well, where the temperature differential is maintained by the fact that the lower part of the vessel 32 is situated in a geothermal environment which is considerably hotter than the upper part of the vessel 32, as described above.

Instead, the embodiment comprising the shorter fluid filled vessel 32 works by the fluid 12 in the interior 26 of the pipe 34 being considerably cooler than the fluid 10 in the exterior 28 of the pipe 34 because it is no longer in contact with the hot rock wall 16. Furthermore, as the thermotunneling converters 38 take heat from the fluid 10 as it travels up vessel 32, it has the effect of cooling the fluid 10 down. Therefore, as the fluid 12 descends down the pipe 34, it will be considerably cooler than the fluid 10 in the exterior 28 of vessel 32, thus creating a temperature differential across thermotunneling converters 38, allowing them to create electricity using the process described above.

In a further embodiment, shown in FIG. 6, the temperature differential is maintained by the introduction of a separate coolant fluid which passes through the center of double-walled inner pipe 34, thus coming into contact with the second surface 20 of the thermotunneling converters 38 and having the effect of maintaining the second surface 20 at a cooler temperature than the first surface 18. In this embodiment the two fluids are separate and have no direct contact with each other. The advantage of this embodiment is that it does not require vessel 32 to be long enough to make use of a temperature gradient between higher and lower levels of rock, and it is more efficient than using the same fluid both as a heat conductor and a heat sink. In this embodiment the coolant fluid could be pumped down into the inner part of pipe 34 from the surface. It could also be pumped past a cooling mechanism. Any suitable pumping and cooling method may be used.

Electrical attachment 37 connects the thermotunneling converters 38 either in series or parallel and conducts the electricity produced by thermotunneling converters 38 through cableway 33 to the surface, where it can be used as an effective electrical source. Attachment 37 is suitably insulated so as to be able to pass through fluid. Any suitable method for conducting electricity to the surface may be used. Series connection of the converters yields a higher voltage output, whereas series connection yields a higher current.

The system may be operated in the following way: Referring now to FIGS. 1, 2 and 3, hot rock 16 provides a geothermal heat source. Thermotunnelling converters 38 are positioned in close proximity to the heat source with first surface 18 of thermotunnneling converters 38 being thermally contacted with hot rock 16. In a preferred embodiment, thermotunneling converters 38 are thermally contacted with hot rock 16 by means of a thermally conductive fluid 10. Cooler fluid 12 provides a heat sink to which second surface 20 of thermotunneling converters 38 are thermally contacted. In one embodiment, fluid 12 is cooled by thermally contacting cooler rock 14. As explained above, when a temperature differential is provided across thermotunnelling converters 38 they will produce electricity. Thermotunnelling converters 38 are connected in series or parallel to electrical attachment 37 and the electricity produced by thermotunnelling converters 38 is conducted through electrical attachment 37 to the surface.

This works as follows: As explained in the prior art section, thermotunneling converters 38 are diode devices made by placing two materials very close to each other so that energetic electrons can tunnel from one material to the next.

By tapping this electron flow, usable electric current can be extracted. The gap between the two materials ensures that the temperature differential between the two sides is maintained. It also allows current to flow in one direction only. Being that the most energetic electrons tunnel, heat is likely to be transferred from the hot side to the cold side along with the current. The gap acts as a heat barrier and prevents the heat from being transferred by mere conduction.

This device allows for the production of electricity by the application of a temperature differential and is therefore ideal for using in a geothermal environment, where a natural temperature gradient exists.

Thus it can be seen that the Geothermal Power Generator of the invention provides an effective way of utilizing natural resources to produce electricity in a relatively cheap manner, using a highly reliable and long lasting system.

While the above description contains many specificities, these should not be construed as limitations on the scope of the invention, but rather as an exemplification of one preferred embodiment thereof. Many other variations are possible. For example, variations could be made in the shape of the generator, the shape and size of the thermotunneling converters, the fluid used and the location used.

Accordingly, the scope of the invention should be determined not by the embodiments illustrated, but by the appended claims and their legal equivalents.

1. Apparatus for generating electricity in a downhole environment comprising:
(a) a fluid filled vessel disposed within said downhole environment, said fluid being in thermal contact with heat dissipated by hot strata in said downhole environment;
(b) a double-walled pipe disposed within said vessel;
(c) a plurality of thermotunneling or thermionic converters located between the two walls of said double-walled pipe, said thermotunneling or thermionic converters each comprising a first surface and a second surface, said first surface being in thermal contact with a fluid around the exterior of said double-walled pipe, said second surface being in thermal contact with a fluid around the interior of said double-walled pipe;
(d) suitable wiring for connecting said thermotunnelling or thermionic converters together and conducting electricity, produced by said thermotunneling or thermionic converters, out of said downhole environment.

2. The apparatus of claim 1 in which there is sufficient space for the fluid to flow around the exterior of said pipe, and wherein said fluid around the exterior of said double-walled pipe, and said fluid around the interior of said double-walled pipe are the same fluid.

3. The apparatus of claim 1 in which said fluid around the exterior of said double-walled pipe, is separated from said fluid around the interior of said double-walled pipe, and where said fluid around the interior of said double-walled pipe is a separate cooling fluid.

4. The apparatus of claim 1 wherein said fluid-filled vessel is of sufficient length that the temperature of the rocks at the top of said vessel is lower than the temperature of the rocks near the bottom of said vessel.

5. The apparatus of claim 1 wherein said apparatus includes a structure supporting said vessel in said downhole environment.

6. The apparatus of claim 5 wherein said supporting structure comprises a vertical shaft positioned through the length of said vessel.

7. The apparatus of claim 6 wherein said shaft provides a cableway for said wiring.

8. The apparatus of claim 6 wherein said supporting structure provides sliding support.

9. The apparatus for generating electricity in a downhole environment of claim 1 wherein said fluid-filled vessel is filled with a thermally conductive fluid.

10. The apparatus for generating electricity in a downhole environment of claim 9 wherein said thermally conductive fluid is selected from the group consisting of liquid graphite, brine, glycerine, water, machine oil and mercury.

11. The apparatus for generating electricity in a downhole environment of claim 1 wherein said fluid-filled vessel comprises a thermally conductive exterior.

12. The apparatus of claim 11 wherein material of said thermally conductive exterior is selected from the group consisting of: copper, aluminum, stainless steel and stainless steel alloys.

13. The apparatus for generating electricity in a downhole environment of claim 1 wherein said pipe is made of a thermally conductive material.

14. The apparatus of claim 13 wherein said thermally conductive material is selected from the group consisting of copper, aluminum, stainless steel and stainless steel alloys.

15. A method for producing electricity comprising the steps of:
a. providing a geothermal-heat source,
b. positioning thermotunneling or thermionic converters in close proximity to said geothermal heat source,
c. thermally contacting a first surface of each of said thermotunneling or thermionic converters to said geothermal heat source,
d. providing a heat sink,
e. thermally contacting a second surface of each of said thermotunneling or thermionic converters to said heat sink,
f. conducting electricity away from said thermotunneling or thermionic converters.

16. The method for generating electricity of claim 15 wherein step c comprises passing a thermally conductive fluid between said heat source and said thermotunnelling converters.

17. The method of claim 16 wherein said step of providing a heat sink comprises circulating a fluid near cool rock.

18. The method of claim 17 wherein said heat source comprises hot rock and wherein said step of thermally contacting a first surface of each of said thermotunneling or thermionic converters to said geothermal heat source comprises circulating said fluid near said hot rock.

19. The method of claim 16 wherein said step of providing a heat sink comprises cooling a thermally conductive fluid.

20. The method of claim 15 further providing the step of electrically connecting said thermotunneling or thermionic converters together.

21. A method for generating electricity in a downhole environment comprising the step of:
applying the temperature gradient of a downhole environment across a thermotunneling or thermionic converter, thereby causing an electric current.
